(19) United States
(12) Patent Application Publication
(10) Pub. No.: US 2024/0306328 A1
(43) Pub. Date: Sep. 12, 2024

(54) QUICK RELEASE MODULE OF DATA STORAGE DEVICE AND HOST CASING HAVING QUICK RELEASE MODULE

(71) Applicant: AETINA CORPORATION, New Taipei City (TW)

(72) Inventors: CHIH-JUNG LO, New Taipei City (TW); YING-JUI HUNG, New Taipei City (TW); YUNG-HO LEE, New Taipei City (TW)

(21) Appl. No.: 18/522,286

(22) Filed: Nov. 29, 2023

Related U.S. Application Data
(60) Provisional application No. 63/451,240, filed on Mar. 10, 2023.

(51) Int. Cl. H05K 5/02

(52) U.S. Cl. CPC H05K 5/0217

(57) ABSTRACT

A quick release module of a data storage device includes a carrier member and a clamp member. The carrier member includes a bottom plate and at least one sidewall. The at least one sidewall is connected to one side of the bottom plate and is provided with a slide track which is parallel to an extension direction of the sidewall. The clamp member includes a connection board and at least one fixing arm. The at least one fixing arm is connected to one end of the connection board and has a slide block slidably disposed on the slide track. When the slide track is located on one end of the slide block, the slide block and the slide track are in mutual interference in a carrying direction of the carrier member. A host casing having the quick release module is also provided.

### CROSS-REFERENCE TO RELATED APPLICATION

This non-provisional application claims priority under 35 U.S.C. § 119 (e) on U.S. provisional Patent Application No. 63/451,240 filed on Mar. 10, 2023, the entire contents of which are hereby incorporated by reference.

### BACKGROUND OF THE INVENTION

### 1. Field of the Invention

The present disclosure relates to a quick release module, and in particular to a quick release module of a data storage device and a host casing having the quick release module.

### 2. Description of the Related Art

In a conventional computer device, various types of data are typically stored on a data storage device. Accompanied with increasing demand for data storage capacity, more data storage devices need to be installed in a computer casing. In general, a data storage device needs to be locked into the computer casing by using hand tools, however, such installation and removal processes are costly and time consuming.

Some tool-free quick release mechanisms and designs are provided in the prior art. However, such quick release mechanisms and designs may encounter issues with difficulties in maintaining stability.

### BRIEF SUMMARY OF THE INVENTION

Therefore, to overcome various issues regarding installation of conventional data storage devices, the present disclosure provides a quick release module of a data storage device and a host casing having the quick release module.

To achieve the above and other objects, the present disclosure provides a quick release module of a data storage device. The quick release module includes a carrier member and a clamp member. The carrier member includes a bottom plate and at least one sidewall. The at least one sidewall is connected to one side of the bottom plate, and is provided with a slide track which is parallel to an extension direction of the sidewall. The clamp member includes a connection board and at least one fixing arm. The at least one fixing arm is connected to one end of the connection board, and has a slide block slidably disposed on the slide track. When the slide track is located on one end of the slide block, the slide block and the slide track are in mutual interference in a carrying direction of the carrier member.

In an embodiment of the present disclosure, the quick release module further includes a fixing member disposed at the connection board. The fixing member fixedly connects the carrier member and the clamp member by means of the fixing member passing through the connection board and the bottom plate.

In an embodiment of the present disclosure, the slide track is a groove provided on the at least one sidewall, and the slide block is a protrusion facing the groove.

In an embodiment of the present disclosure, the carrier member includes two sidewalls parallel to each other, the clamp member includes two fixing arms, and the two fixing arms are parallel to each other and are connected to two ends of the connection board, respectively.

In an embodiment of the present disclosure, the two sidewalls are respectively provided with the two slide tracks, and the two fixing arms respectively have the two slide blocks corresponding to positions of the two slide tracks.

In an embodiment of the present disclosure, the clamp member further includes a covering. The cover and the bottom plate are clamped to form an accommodation space for the data storage device.

In an embodiment of the present disclosure, the at least one fixing arm is provided with a lock hole.

The present disclosure further provides a host casing having the quick release module. The host casing includes a casing body, an upper cover rotatably disposed at the casing body, and the quick release module of a data storage device described above, disposed on a surface of the upper cover facing the casing body.

Thus, the quick release module of a data storage device and the host casing having the quick release module allow the data storage device to be quickly installed or removed in a tool-free manner from the carrier member, thereby enhancing ease of assembly.

### BRIEF DESCRIPTION OF THE DRAWINGS

FIG. 1 is a perspective schematic diagram of a quick release module according to an embodiment of the present disclosure.

FIG. 2 is an assembly schematic diagram of the quick release module according to an embodiment of the present disclosure.

FIG. 3 is a perspective schematic diagram of a host casing having the quick release module according to an embodiment of the present disclosure.

### DETAILED DESCRIPTION OF THE INVENTION

To fully understand the present disclosure, the present disclosure is described in detail by way of specific embodiments with the accompanying drawings. A person skilled in the art would be able to understand the objects, features, and effects of the present disclosure on the basis of the disclosure of the present application. It should be noted that, the present disclosure may be implemented or applied by other specific embodiments, and changes and modifications may also be made on the basis of different perspectives and applications to various details in the description without departing from the spirit of the present disclosure. Technical contents associated with the present disclosure are described in detail below, and it should be noted that the disclosure is not to be construed as limitations to the scope of claims of the present disclosure. Associated details are as given in the description below.

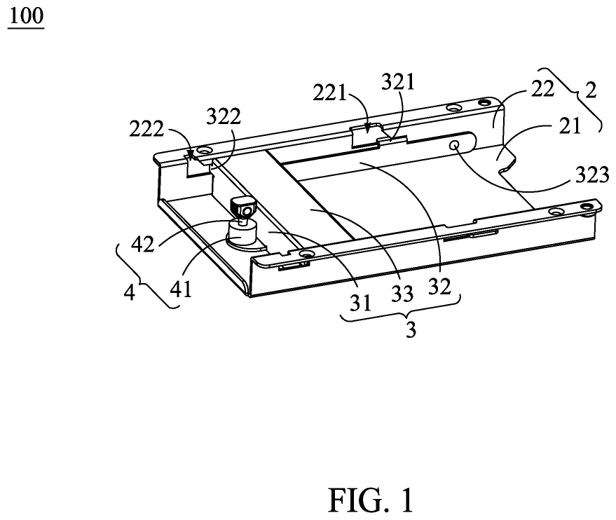

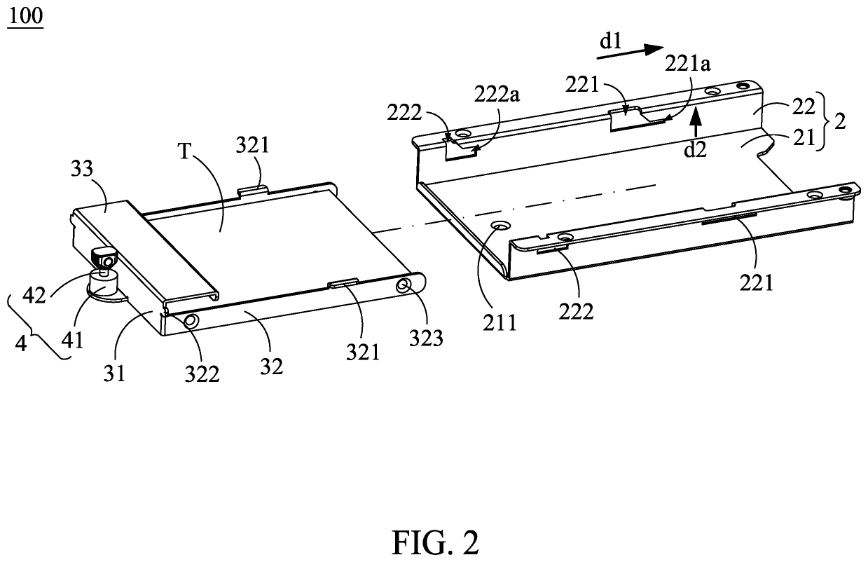

As shown in FIG. 1 and FIG. 2, a quick release module 100 of a data storage device according to an embodiment of the present disclosure includes a carrier member 2 and a clamp member 3.

The carrier member 2 includes a bottom plate 21 and at least one sidewall 22. The at least one side wall 22 is connected to one side of the bottom plate 21, and is provided with a slide track 221 which is parallel to an extension direction d1 of the sidewall 22. The bottom plate 21 is used for carrying a data storage device T, for example, a solid-state drive (SSD), a hybrid hard drive (HHD), or a hard disk drive (HDD). The carrier member 2 can be an integral or a non-integral structure. When the carrier member 2 is implemented as an integral structure, the ease of manufacturing can be enhanced. The carrier member 2 may be made of metal or alloy, for example, iron, copper, or aluminum alloy.

The clamp member 3 includes a connection board 31 and at least one fixing arm 32. The at least one fixing arm 32 is connected to one end of the connection board 31 and has a slide block 321. The slide block 321 is slidably disposed on the slide track 221.

Execution details of installation and removal of the quick release module 100 of a data storage device of the present disclosure are described below.

First of all, the data storage device T to be installed is placed in the clamp member 3. In this embodiment, preferably, the data storage device T is clamped by two fixing arms 32 parallel to each other, and a screw is used to pass through a lock hole 323 on the fixing arm 32 so as to fix the data storage device T. However, the present disclosure is not limited to the example above. In other embodiments, the clamp member 3 can have only one fixing arm 32, or the screw can be replaced by other fastening or attaching means to fix the data storage device T.

Next, the clamp member 3 installed with the data storage device T is placed and slid into the carrier member 2 along the extension direction d1 of the sidewall 22. When the bottom plate 21 carries the data storage device T, and the slide block 321 of the fixing arm 32 is slid into the slide track 221 and is located on one end of the slide track 221, the slide block 321 and the slide track 221 are in mutual interference in a carrier direction d2 (usually perpendicular to the bottom plate 21) of the carrier member 2. That is to say, unless the clamp member 3 is withdrawn in an opposite direction of the extension direction d1, the clamp member 3 and the carrier member 2 are in mutual interference, such that the data storage device T is stably accommodated on the bottom plate 21.

To further prevent the clamp member 3 from being unintentionally withdrawn in an opposite direction of the extension direction d1, the quick release module 100 of a data storage device can further include a fixing member 4 disposed on the connection board 31. The fixing member 4 fixedly connects the carrier member 2 and the clamp member 3 by means of the fixing member 4 passing through the connection board 31 and an opening 211 of the bottom plate 21. The fixing member 4 includes a base 41 and a tie rod 42. The base 41 is fixed at the connection board 31, and the tie rod 42 is movably disposed at the base 41. When the clamp member 3 is pushed into position, that is, when the slide block 321 slides into an end 221a of the slide track 221, the clamp member 3 and the carrier member 2 are in mutual interference. At this point, the tie rod 42 is pressed, so that the tie rod 42 passes through the connection board 31 and the opening 211 of the bottom plate 21 and fixedly connects the carrier member 2 and the clamp member 3. The clamp member 3 is no longer able to be withdrawn from the carrier member 2 in an opposite direction of the extension direction d1.

On the other hand, to quickly release the data storage device T, the tie rod 42 is first pulled to release its fixing effect on the carrier member 2 and the clamp member 3. The clamp member 3 is caused to slide so that it withdraws in an opposite direction of the extension direction d1, relieving mutual interference between the slide block 321 and the slide track 221 in the carrying direction d2, thereby separating the clamp member 3 and the carrier member 2. Lastly, the locking between the clamp member 3 and the data storage device T is released, thus completing quick release of the data storage device T. However, the present disclosure is not limited to the examples above. Design details related to the fixing member 4 can be modified by other means, so as to fix the carrier member 2 and the clamp member 3.

In conclusion, when the data storage device T needs maintenance or replacement, the quick release module 100 of a data storage device allows the data storage device T to be quickly installed or removed in a tool-free manner from the carrier member 2, thereby enhancing ease of assembly. The present disclosure uses the mechanism and design of the carrier member 2 and clamp member 3 to enhance a shock absorption ability of the data storage device T. When the carrier member 2 and the clamp member 3 are combined, the assembly stability can be reinforced, and the matched positioning between the slide blocks and the slide tracks can also reinforce assembly stability.

As shown in FIG. 1 and FIG. 2, in an embodiment, the slide track 221 has a form of a groove provided on the sidewall 22, wherein the groove is substantially L-shaped. The slide block 321 has a form of a protrusion facing the groove. However, the present disclosure is not limited to the examples above. The specific form of the slide track 221 and the specific form of the slide block 321 can be changed according to requirements.

Further, as described in the embodiment above, if the clamp member 3 includes two fixing arms 32, the carrier member 2 can correspondingly include two sidewalls 22 parallel to each other, and only one of the sidewalls 22 has the slide track 221 or both of the sidewalls 22 have the slide tracks 221. The two fixing arms 32 parallel to each other are respectively connected to two ends of the connection board 31. If only one of the sidewalls 22 of the carrier member 2 has the slide track 221, then only one of the fixing arms 32 has the corresponding slide block 321. If both of the sidewalls have the slide tracks 221, then the clamp member 3 can be configured to have only one of the fixing arms 32 be provided with the slide block 321, or have both of the fixing arms 32 be provided with the slide blocks 321 corresponding to the two slide tracks 221 respectively.

Further, in an embodiment, the carrier member 2 includes two sidewalls 22 parallel to each other, the two sidewalls 22 each have two slide tracks 221 and 222, and the two fixing arms 32 each have two slide blocks 321 and 322 corresponding to positions of the two slide tracks. The two slide tracks 221 and 222 can have completely identical forms or slightly different forms, and the two slide blocks 321 and 322 can also have completely identical forms or slightly different forms. The slide block 321 is slidably disposed at the slide track 221, and when the slide block 321 is located on the end 221a of the slide track 221, the clamp member 3 and the carrier member 2 are in mutual interference in the carrying direction d2. Similarly, the slide block 322 is slidably disposed at the slide track 222, and when the slide block 322 is located on an end 222a of the slide track 222, the clamp member 3 and the carrier member 2 are in mutual interference in the carrying direction d2.

Further, in an embodiment, the clamp member 3 further includes a cover 33. The cover 33 and the bottom plate 21 are clamped to form an accommodation space for the data storage device, so as to stably fix the data storage device T.

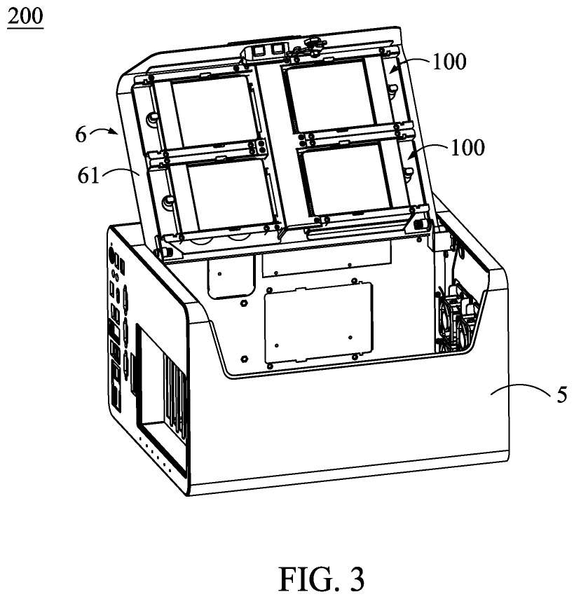

Further, as shown in FIG. 3, the present disclosure further provides a host casing 200 having the quick release module. The host casing 200 includes a casing body 5, an upper cover 6, and the quick release module 100 of a data storage device described above.

The upper cover 6 is rotatably disposed at the casing body 5, and the upper cover 6 and the casing body 5 are clamped to form a space for storing a host.

The quick release module 100 of a data storage device is disposed on a surface 61 of the upper cover 6 facing the casing body 5. Multiple quick release modules 100 of a data storage device can be disposed on the surface 61 of the upper cover 6, and a number of the quick release module is four in this embodiment, however, the present disclosure is not limited to such an example.

When the carrier member 2 and the clamp member 3 are combined, a connector of the data storage device T can further be fixed with a connection base of the upper cover 6 to reinforce assembly stability, hence enhancing the overall shock absorption ability of the data storage device T installed at the host casing.

The present invention is described by way of the embodiments above. A person skilled in the art should understand that these embodiments are merely for describing the present invention and are not to be construed as limitations to the scope of the present invention. It should be noted that all equivalent changes, replacements and substitutions made to the embodiments are to be encompassed within the scope of the present invention. Therefore, the scope of protection of the present invention should be accorded with the broadest interpretation of the appended claims.

What is claimed is:

1. A quick release module of a data storage device, comprising:
a carrier member, comprising a bottom plate and at least one sidewall, wherein the at least one sidewall is connected to one side of the bottom plate and is provided with a slide track which is parallel to an extension direction of the sidewall; and
a clamp member, comprising a connection board and at least one fixing arm, wherein the at least one fixing arm is connected to one end of the connection board and has a slide block, and the slide block is slidably disposed on the slide track;
wherein the slide block is located on one end of the slide track, and the slide block and the slide track are in mutual interference in a carrying direction of the carrier member.

2. The quick release module of a data storage device according to claim 1, further comprising:
a fixing member, disposed at the connection board, the fixing member fixedly connecting the carrier member and the clamp member by means of passing through the connection board and the bottom plate.

3. The quick release module of a data storage device according to claim 1, wherein the slide track is a groove provided on the at least one sidewall, and the slide block is a protrusion facing the groove.

4. The quick release module of a data storage device according to claim 1, wherein the carrier member comprises two sidewalls parallel to each other, the clamp member comprises two fixing arms, and the two fixing arms are parallel to each other and are connected to two ends of the connection board, respectively.

5. The quick release module of a data storage device according to claim 4, wherein the two sidewalls are respectively provided with the two slide tracks, and the two fixing arms respectively have the two slide blocks corresponding to positions of the slide tracks.

6. The quick release module of a data storage device according to claim 1, wherein the clamp member further comprises a cover, and the cover and the bottom plate are clamped to form an accommodation space for the data storage device.

7. The quick release module of a data storage device according to claim 1, wherein the at least one fixing arm is provided with a lock hole.

8. A host casing having a quick release module, comprising:
a casing body;
an upper cover, rotatably disposed at the casing body; and
the quick release module of a data storage device according to claim 1, disposed on one surface of the upper cover facing the casing body.
